(19) United States
(12) Patent Application Publication
(10) Pub. No.: US 2024/0368755 A1
(43) Pub. Date: Nov. 7, 2024

(54) METHOD FOR REMOVING MOLYBDENUM MONOFLUORIDE TO MOLYBDENUM PENTAFLUORIDE AND METHOD FOR PRODUCING SEMICONDUCTOR DEVICE

(71) Applicant: CENTRAL GLASS CO., LTD., Ube-shi, Yamaguchi (JP)

(72) Inventors: Akiou KIKUCHI, Yamaguchi (JP); Masato SHINAGAWA, Yamaguchi (JP)

(21) Appl. No.: 18/576,416

(22) PCT Filed: Jun. 29, 2022
(86) PCT No.: PCT/JP2022/026026

§ 371 Date: Jan. 4, 2024

(30) Foreign Application Priority Data
Jul. 5, 2021 (JP) 2021-111738

(51) Int. Cl. C23C 16/44; C23C 16/14; H01L 21/3205

(52) U.S. Cl. CPC C23C 16/4405; C23C 16/14; H01L 21/32051

(57) ABSTRACT

The present invention relates to a method for removing MoFₓ or MoFₓ and MoOFₓ, including: bringing a halogen-containing gas into contact with a member having a deposit or a coating of MoFₓ or MoFₓ and MoOFₓ (where x represents a number greater than 0 and less than 6); and removing MoFₓ or MoFₓ and MoOFₓ from the member, a method for removing a deposit or a coating from a member having the deposit or the coating of MoFₓ or MoFₓ and MoOFₓ mixed as impurities in MoF₆ by a method for producing a semiconductor device including the above removing method, and a method for producing a semiconductor device that includes removing a deposit or a coating from a semiconductor device production apparatus having a deposit or coating of MoFₓ or MoFₓ and MoOFₓ, and that can avoid clogging or contamination of the production apparatus.

### TECHNICAL FIELD

The present invention relates to a method for removing molybdenum monofluoride to molybdenum pentafluoride and a method for producing a semiconductor device.

### BACKGROUND ART

Molybdenum hexafluoride (MoF₆) is used as a raw material for depositing molybdenum metal by chemical vapor deposition (CVD) in production of semiconductor devices, solar cells, and the like.

In addition, MoF₆ is used as an etching material in a process of producing a semiconductor device (Patent Literature 1).

Paragraph in Patent Literature 2 discloses that unreacted elemental metal (Mo) and intermediates of molybdenum monofluoride to molybdenum pentafluoride (MoF, MoF₂, MoF₃, MoF₄, MoF₅) may be mixed as impurities during the production of MoF₆, and such impurities not only cause a decrease in a purity of MoF₆, but also may accumulate inside a reaction device, and this may cause a problem of clogging in a reaction system and a problem in maintenance of the reaction device.

### CITATION LIST

### Patent Literature

Patent Literature 1: JP2019-502253A
Patent Literature 2: WO 2019/189715

### SUMMARY OF INVENTION

### Technical Problem

A method for removing a deposit or a coating of MoFₓ (x represents a number greater than 0 and less than 6, and the same applies to x below), or MoFₓ and MoOFₓ, from a member having the deposit or the coating of MoFₓ mixed as impurities in MoF₆, or a member having the deposit or the coating of MoFₓ and MoOFₓ mixed as impurities in MoF 6 is desired.

In addition, when MoF₆ is used as a film-forming material or an etching material for Mo in the process of producing a semiconductor device, a method for stably producing a semiconductor device that includes removing a deposit or a coating of MoFₓ or a deposit or a coating of MoFₓ and MoOFₓ, from a semiconductor device production apparatus (for example, a chamber or a pipe) having a deposit or a coating of MoFₓ or a deposit or a coating of MoFₓ and MoOFₓ mixed as impurities in MoF₆, and that can avoid clogging and contamination of the production apparatus is desired.

The present invention has been made in view of the above circumstances, and an object thereof is to provide a method for removing a deposit or a coating of MoFₓ or MoFₓ and MoOFₓ mixed as impurities in MoF₆ from a member having the deposit or the coating of MoFₓ or MoFₓ and MoOFₓ, and a method for producing a semiconductor device that includes removing a deposit or a coating of MoFₓ or MoFₓ and MoOFₓ from a semiconductor device production apparatus (for example, a chamber or a pipe) having the deposit or the coating of MoFₓ or MoFₓ and MoOFₓ, and that can avoid clogging or contamination of the production apparatus.

### Solution to Problem

As a result of extensive studies in view of such a problem, the present inventors have found that when a member having a deposit or a coating of MoFₓ or MoFₓ and MoOFₓ is brought into contact with a halogen-containing gas, the deposit or the coating can be removed from the member.

That is, the present inventors have found that the above problem can be solved by the following configurations.

[1]

A method for removing MoFₓ or MoFₓ and MoOFₓ, including:
bringing a halogen-containing gas into contact with a member having a deposit or a coating of MoFₓ or MoFₓ and MoOFₓ; and
removing MoFₓ or MoFₓ and MoOFₓ from the member, where x represents a number greater than 0 and less than 6.
   [2]

The method for removing MoFₓ or MoFₓ and MoOFₓ according to [1], in which the halogen-containing gas is a gas of a compound having a bond between a fluorine atom and an atom other than the fluorine atom, and a bond energy between the fluorine atom and the atom other than the fluorine atom is 2.5 eV or less.

[3]

The method for removing MoFₓ or MoFₓ and MoOFₓ according to [2], in which the bond energy is 1.7 eV or more and 2.5 eV or less.

[4]

The method for removing MoFₓ or MoFₓ and MoOFₓ according to [1], in which the halogen-containing gas is a fluorine-containing gas.

[5]

The method for removing MoFₓ or MoFₓ and MoOFₓ according to [1], in which the halogen-containing gas is a fluorine gas.

[6]

The method for removing MoFₓ or MoFₓ and MoOFₓ according to any one of [1] to [5], in which the member with which the halogen-containing gas is brought into contact has a temperature of 0° C. to 400° C.

[7]

A method for producing a semiconductor device including:
(1) circulating a gas containing MoF₆ in a semiconductor processing apparatus including a chamber and a pipe connected to the chamber to bring MoF₆ into contact with a semiconductor substrate; and
(2) bringing a halogen-containing gas into contact with at least one of the chamber and the pipe having a deposit or coating of MoFₓ or MoFₓ and MoOFₓ, in which where x represents a number greater than 0 and less than 6.
   [8]

The method for producing a semiconductor device according to [7], in which the halogen-containing gas is a gas of a compound having a bond between a fluorine atom and an atom other than the fluorine atom, and a bond energy between the fluorine atom and the atom other than the fluorine atom is 2.5 eV or less.

[9]

The method for producing a semiconductor device according to [8], in which the bond energy is 1.7 eV or more and 2.5 eV or less.

[10]

The method for producing a semiconductor device according to [7], in which the halogen-containing gas is a fluorine-containing gas.

[11]

The method for producing a semiconductor device according to [7], in which the halogen-containing gas is a fluorine gas.

[12]

The method for producing a semiconductor device according to any one of [7] to [11], in which at least one of the chamber or the pipe with which the halogen-containing gas is brought into contact has a temperature of 0° C. to 400° C.

### Advantageous Effects of Invention

The present invention allows for providing a method for removing a deposit or a coating of of MoFₓ or MoFₓ and MoOFₓ mixed as impurities in MoF₆, from a member having the deposit or the coating of MoFₓ or MoFₓ and MoOFₓ, and a method for stably producing a semiconductor device that includes removing a deposit or a coating from a semiconductor device production apparatus (for example, a chamber or a pipe) having a deposit or coating of MoFₓ or MoFₓ and MoOFₓ, and that can avoid clogging or contamination of the production apparatus.

### DESCRIPTION OF EMBODIMENTS

Configurations and combinations thereof in the following embodiments are merely examples, and configuration additions, omissions, replacements, and other changes are possible without departing from the scope of the present invention. In addition, the present invention is not limited by the embodiments.

In the present description, the expression “to” is used to include numerical values before and after it as a lower limit value and an upper limit value.

[Method for Removing MoFₓ or MoFₓ and MoOFₓ]

A method for removing MoFₓ or MoFₓ and MoOFₓ according to the present invention is a method for removing MoFₓ or MoFₓ and MoOFₓ including: bringing a halogen-containing gas into contact with a member having a deposit or coating of MoFₓ or MoFₓ and MoOFₓ; and removing MoFₓ or MoFₓ and MoOFₓ from the member. where x represents a number greater than 0 and less than 6.

Although details of a mechanism of removing MoFₓ or MoFₓ and MoOFₓ by the removing method according to the present invention are not clear, the present inventors presume as follows.

Molybdenum monofluoride to molybdenum pentafluoride (MoFₓ, or MoFₓ and MoOFₓ) have a boiling point higher than a boiling point of MoF₆, and tend to remain on a surface of a member or inside a semiconductor device production apparatus. For example, MoF₆ has a boiling point of 35° C. at 1 atm, whereas MoF₅ has a boiling point of 214° C. at 1 atm.

As described above, MoFₓ or MoFₓ and MoOFₓ have a high boiling point, and thus tend to remain on the surface of the member and inside the semiconductor device production apparatus.

In the present invention, it is considered that when a halogen-containing gas is brought into contact with MoFₓ or MoFₓ and MoOFₓ, MoFₓ or MoFₓ and MoOFₓ can be oxidized and converted to compounds having lower boiling points, and MoFₓ or MoFₓ and MoOFₓ can be removed.

MoFₓ as a removal target may be MoFₓ and an oxyfluoride (MoOFₓ) to which a part (for example, a surface layer) of MoFₓ changed. When the above MoFₓ is deposited or coated and the chamber is open to an active atmosphere containing air or the like, the surface layer may be an oxyfluoride (see, for example, J. Flu. Chem, 11, 6, 629 (1978) and Stu. Inorg. Chem, 19, 251 (1994)). The removing method and a method for producing a semiconductor device according to the present invention can also be applied to MoFₓ whose surface is oxidized. When MoFₓ and MoOFₓ are mixed, the mixture may be collectively referred to as “MoO_{y}F_{z}” based on abundance ratios thereof. In this case, y is greater than 0 and less than 3 and z is greater than 0 and less than 6. Weight measurement of the deposit allows to confirm that the deposit is MoFₓ. In addition, X-ray diffraction (XRD) measurement and weight measurement of the deposit allows to confirm that the deposit is a mixture of MoFₓ and MoOFₓ.

### (Halogen-Containing Gas)

The halogen-containing gas is not limited as long as it is a gas containing halogen, and is preferably a fluorine-containing gas (a gas containing fluorine).

Examples of the fluorine-containing gas include a fluorine gas (F₂ gas), a chlorine fluoride gas (ClF gas), a chlorine trifluoride gas (ClF₃ gas), a bromine fluoride gas (BrF gas), a bromine trifluoride gas (BrF₃ gas), a bromine pentafluoride gas (BrF₅ gas), an iodine pentafluoride gas (IF₅ gas), an iodine heptafluoride gas (IF₇ gas), an oxygen difluoride gas (OF₂ gas), a xenon difluoride gas (XeF₂ gas), a xenon tetrafluoride gas (XeF₄ gas), a molybdenum hexafluoride gas (MoF₆ gas), a NF₃ gas, a CF₄ gas, a C₂F₆ gas, or a mixed gas thereof.

Preferably, the halogen-containing gas is a gas of a compound having a bond between a fluorine atom and an atom other than the fluorine atom, and a bond energy between the fluorine atom and the atom other than the fluorine atom is 2.5 eV or less. The “atom other than the fluorine atom” may be a fluorine atom. Examples of the gas include a compound represented by the following formula (1).

MFₙ (1)
[M is a fluorine atom, a chlorine atom, a bromine atom, an iodine atom, an oxygen atom, or a rare gas (argon, xenon or krypton) atom, and n is a number of 1 to 7.]

Specifically, the compound represented by the formula (1) is preferably a fluorine gas (F₂ gas), a chlorine trifluoride gas (ClF₃ gas), an iodine heptafluoride gas (IF₇ gas), or a molybdenum hexafluoride gas (MoF₆ gas), more preferably a chlorine trifluoride gas (ClF₃ gas) or an iodine heptafluoride gas (IF₇ gas), and particularly preferably a chlorine trifluoride gas (ClF₃ gas).

More preferably, the halogen-containing gas is a gas of a compound having a bond between a fluorine atom and an atom other than the fluorine atom, and the bond energy between the fluorine atom and the atom other than the fluorine atom is 1.7 eV or more and 2.5 eV or less.

The halogen-containing gas may be diluted with an inert gas such as a nitrogen gas, helium, argon or neon.

### (Member)

The member to which the method for removing MoFₓ or MoFₓ and MoOFₓ according to the present invention is applied is not limited.

The member is, for example, a pipe, a chamber, or a storage container.

A material constituting the member is not limited, but is preferably a metal, and examples thereof include a metal such as stainless steel, manganese steel, aluminum, an aluminum alloy, nickel, and a nickel alloy.

The stainless steel is not limited, but for example, martensitic stainless steel, ferritic stainless steel, austenitic stainless steel, and other stainless steel can be used. SUS304, SUS304L, SUS316, and SUS316L are particularly preferred.

The manganese steel is not limited, but for example, SMn420, SMn433, SMn438, and SMn443 defined in JIS G 4053:2016, or STH11 and STH12 defined in JIS G 3429:2013 can be used.

The aluminum alloy is not limited, but for example, alloys of aluminum with copper, manganese, silicon, magnesium, zinc, nickel, or the like can be used.

The nickel alloy is not limited, but for example, Hastelloy or Inconel can be used.

The surface of the member may be subjected to mirror finishing, acid washing, electropolishing, or surface coating.

A temperature of the member with which the halogen-containing gas is brought into contact is not limited, but is preferably 0° C. to 400° C., more preferably 20° C. to 200° C., and still more preferably 40° C. to 150° C.

A pressure during the contact with the halogen-containing gas is not limited, but can be appropriately set in a range of, for example, 1×10⁻⁵ kPa to 1000 kPa, preferably 1×10⁻⁴ kPa to 300 kPa, and more preferably 1×10⁻³ kPa to 100 kPa.

A time of the contact with the halogen-containing gas is not limited, but can be appropriately set in a range of, for example, 1 second or longer and 24 hours or shorter, preferably 10 seconds or longer and 10 hours or shorter, and more preferably 30 seconds or longer and 1 hour or shorter.

### [Method for Producing Semiconductor Device]

The method for producing a semiconductor device according to the present invention is a method for producing a semiconductor device including:
(1) circulating a gas containing MoF₆ in a semiconductor processing apparatus including a chamber and a pipe connected to the chamber to bring MoF₆ into contact with a semiconductor substrate; and
(2) bringing a halogen-containing gas into contact with at least one of the chamber and the pipe having a deposit or a coating of MoFₓ or MoFₓ and MoOFₓ, where x represents a number greater than 0 and less than 6.

A material constituting the chamber of the semiconductor processing apparatus and a material constituting the pipe connected to the chamber in the method for producing a semiconductor device according to the present invention are the same as the material constituting the member described in the above method for removing MoFₓ or MoFₓ and MoOFₓ.

The gas containing MoF₆ in the above step (1) may be a gas containing 100 vol % of MoF₆, or a gas obtained by diluting MoF₆ with an inert gas such as nitrogen or argon.

When the gas containing MoF₆ is circulated in the semiconductor processing apparatus, for example, a Mo film can be formed on the substrate. Alternatively, when the gas containing MoF₆ is circulated in the semiconductor processing apparatus, for example, from a substrate having a layer such as an oxide film formed thereon, at least a part of the layer can be etched. By performing these treatments, a semiconductor device can be produced.

The above step (2) is bringing a halogen-containing gas into contact with MoFₓ or MoFₓ and MoOFₓ that is deposited and coated and mixed as impurities in MoF₆ used in the step (1). By the contact with the halogen-containing gas, MoFₓ or MoFₓ and MoOFₓ can be removed and the clogging or contamination of the production apparatus can be avoided.

The halogen-containing gas in the above step (2) is the same as the halogen-containing gas described in the above method for removing MoFₓ or MoFₓ and MoOFₓ.

A temperature of at least one member of the chamber and the pipe with which the halogen-containing gas is brought into contact is not limited, but is preferably 0° C. to 400° C., more preferably 20° C. to 200° C., and still more preferably 40° C. to 150° C.

A pressure during the contact with the halogen-containing gas is not limited, but can be appropriately set in a range of, for example, 1×10⁻⁵ kPa to 1000 kPa, preferably 1× 10-4 kPa to 300 kPa, and more preferably 1×10⁻³ kPa to 100 kPa.

A time of the contact with the halogen-containing gas is not limited, but can be appropriately set in a range of, for example, 1 second or longer and 24 hours or shorter, preferably 10 seconds or longer and 10 hours or shorter, and more preferably 30 seconds or longer and 1 hour or shorter.

### EXAMPLE

The present invention will be described in more detail below with reference to Examples, but the present invention is not limited by these descriptions.

Experiments using an actual semiconductor production apparatus to deposit and clog MoFₓ or MoFₓ and MoOFₓ, and to bring MoFₓ or MoFₓ and MoOFₓ into contact with a predetermined gas such as a halogen-containing gas are difficult due to restrictions on the apparatus. Therefore, in the present Examples, MoFₓ or MoFₓ and MoOFₓ as removal targets were produced on purpose in a model experiment, and the method according to the present invention was applied thereto for evaluation.

### <Model Experiment (1)> Reproduction of Deposition of MoFₓ

To a Ni tube having a tube diameter of 25 mm and a volume of 100 ml was charged a Mo powder, thereafter MoF₆ was introduced. The Ni tube was sealed, followed by a reaction for 1 hour under conditions of an internal temperature of 150° C. and an internal pressure of 70 kPa, thereby depositing MoFₓ (x represents a number greater than 0 and less than 6) on purpose. It was confirmed based on a weight increase amount of the deposit, that an average composition thereof was MoF 3.0.

### (Comparative Example 1) Contact of Oxygen Gas with MoFₓ

To a container containing the deposit obtained in the model experiment (1) was introduced an oxygen gas, which is a combustion-supporting gas sometimes used for chamber cleaning. The oxygen gas was brought into contact with the deposit at an internal temperature of 100° C. and an internal pressure of 10 kPa. However, the deposit was still present in the container even after 1 hour of contact.

### (Example 1-1) Contact of Fluorine Gas with MoFₓ

To a container containing the deposit obtained in the model experiment (1) was introduced a fluorine gas as a halogen-containing gas. The fluorine gas was brought into contact with the deposit at an internal temperature of 100° C. and an internal pressure of 10 kPa, 34.3 mass % of the deposit disappeared after 2 minutes of contact. In addition, after 10 minutes of contact, the entire deposit disappeared.

### (Example 1-2) Contact of ClF₃ Gas with MoFₓ

To a container containing the deposit obtained in the model experiment (1) was introduced a chlorine trifluoride gas as a halogen-containing gas. The chlorine trifluoride gas was brought into contact with the deposit at an internal temperature of 100° C. and an internal pressure of 10 kPa, 87.1 mass % of the deposit disappeared after 2 minutes of contact. In addition, after 4 minutes of contact, the entire deposit disappeared.

### (Example 1-3) Contact of IF₇ Gas with MoFₓ

To a container containing the deposit obtained in the model experiment (1) was introduced an iodine heptafluoride gas as a halogen-containing gas. The iodine heptafluoride gas was brought into contact with the deposit at an internal temperature of 100° C. and an internal pressure of 10 kPa, 41.0 mass % of the deposit disappeared after 2 minutes of contact. In addition, after 8 minutes of contact, the entire deposit disappeared.

### (Example 1-4) Contact of MoF₆ Gas with MoFₓ

To a container containing the deposit obtained in the model experiment (1) was introduced a molybdenum hexafluoride gas as a halogen-containing gas. The molybdenum hexafluoride gas was brought into contact with the deposit at an internal temperature of 100° C. and an internal pressure of 10 kPa, 41.0 mass % of the deposit disappeared after 2 minutes of contact. In addition, after 8 minutes of contact, the entire deposit disappeared.

### <Model Experiment (2)> Reproduction of Deposition of Mixture of MoFₓ and

Oxyfluoride thereof (MoOFₓ)

To a Ni tube having a tube diameter of 25 mm and a volume of 100 ml was charged a MoO₃ powder, thereafter MoF₆ was introduced. The Ni tube was sealed, followed by a reaction for 1 hour under conditions of an internal temperature of 170° C. and an internal pressure of 70 kPa, thereby depositing a mixture of MoFₓ and MoOFₓ (x represents a number greater than 0 and less than 6) on purpose. By X-ray diffraction (XRD) measurement and weight measurement of the deposit, it was confirmed that the deposit was a mixture of MoFₓ and MoOFₓ.

### (Comparative Example 2) Contact of Oxygen Gas with Mixture of MoFₓ and MoOFₓ

To a container containing the deposit obtained in the model experiment (2) was introduced an oxygen gas, which is a combustion-supporting gas sometimes used for chamber cleaning. The oxygen gas was brought into contact with the deposit at an internal temperature of 130° C. and an internal pressure of 10 kPa, but the deposit was still present in the container even after 1 hour of contact.

### (Example 2-1) Contact of Fluorine Gas with Mixture of MoFₓ and MoOFₓ

To a container containing the deposit obtained in the model experiment (2) was introduced a fluorine gas as a halogen-containing gas. The fluorine gas was brought into contact with the deposit at an internal temperature of 130° C. and an internal pressure of 10 kPa, 28.1 mass % of the deposit disappeared after 2 minutes of contact. In addition, after 10 minutes of contact, the entire deposit disappeared.

### (Example 2-2) Contact of ClF₃ Gas with Mixture of MoFₓ and MoOFₓ

To a container containing the deposit obtained in the model experiment (2) was introduced a chlorine trifluoride gas as a halogen-containing gas. The chlorine trifluoride gas was brought into contact with the deposit at an internal temperature of 130° C. and an internal pressure of 10 kPa, 92.6 mass % of the deposit disappeared after 2 minutes of contact. In addition, after 4 minutes of contact, the entire deposit disappeared.

### (Example 2-3) Contact of IF₇ Gas with Mixture of MoFₓ and MoOFₓ

To a container containing the deposit obtained in the model experiment (2) was introduced an iodine heptafluoride gas as a halogen-containing gas. The iodine heptafluoride gas was brought into contact with the deposit at an internal temperature of 130° C. and an internal pressure of 10 kPa, 31.0 mass % of the deposit disappeared after 2 minutes of contact. In addition, after 8 minutes of contact, the entire deposit disappeared.

### (Example 2-4) Contact of MoF₆ Gas with Mixture of MoFₓ and MoOFₓ

To a container containing the deposit obtained in the model experiment (2) was introduced a molybdenum hexafluoride gas as a halogen-containing gas. The molybdenum hexafluoride gas was brought into contact with the deposit at an internal temperature of 130° C. and an internal pressure of 10 kPa, 31.0 mass % of the deposit disappeared after 2 minutes of contact. In addition, after 8 minutes of contact, the entire deposit disappeared.

Table 1 below summarizes removal rates in the above Examples and Comparative Examples after contact for 2 minutes with each of the gases used.

TABLE 1

| | | Bond | | | Contact | Removal | |
|---|---|---|---|---|---|---|---|
| Removal | Gas | energy* | Temperature | Pressure | time | rate | |
| target | species | [eV] | [° C.] | [kPa] | [min.] | [mass %] | |
| MoFₓ | O₂ | — | 100 | 10 | 2 | <1 | Comparative |
| | | | | | | | Example 1 |
| | F₂ | 1.6 | 100 | 10 | 2 | 34.3 | Example 1-1 |
| | ClF₃ | 1.8 | 100 | 10 | 2 | 87.1 | Example 1-2 |
| | IF₇ | 2.4 | 100 | 10 | 2 | 41.0 | Example 1-3 |
| Mixture of | O₂ | — | 130 | 10 | 2 | <1 | Comparative |
| MoFₓ and | | | | | | | Example 2 |
| MoOFₓ | F₂ | 1.6 | 130 | 10 | 2 | 28.1 | Example 2-1 |
| | ClF₃ | 1.8 | 130 | 10 | 2 | 92.6 | Example 2-2 |
| | IF₇ | 2.4 | 130 | 10 | 2 | 31.0 | Example 2-3 |

*the bond energy between a fluorine atom and an atom other than the fluorine atom when the halogen-containing gas is a compound gas containing a bond between the fluorine atom and the atom other than the fluorine atom

As is clear from Table 1, the removing method according to the present invention of contact with the halogen-containing gas has a high removal rate of MoFₓ or MoFₓ and MoOFₓ.

### INDUSTRIAL APPLICABILITY

The present invention allows for providing a method for removing a deposit or a coating of of MoFₓ or MoFₓ and MoOFₓ mixed as impurities in MoF₆, from a member having the deposit or the coating of MoFₓ or MoFₓ and MoOFₓ, and a method for stably producing a semiconductor device that includes removing a deposit or a coating from a semiconductor device production apparatus (for example, a chamber or a pipe) having a deposit or coating of MoFₓ or MoFₓ and MoOFₓ, and that can avoid clogging or contamination of the production apparatus.

Although the present invention has been described in detail and with reference to specific examples, it will be apparent to those skilled in the art that various changes and modifications can be made without departing from the spirit and scope of the present invention.

The present application is based on a Japanese Patent Application (No. 2021-111738) filed on Jul. 5, 2021, the contents of which are incorporated herein by reference.

1. A method for removing MoFₓ or MoFₓ and MoOFₓ, comprising:
bringing a halogen-containing gas into contact with a member having a deposit or a coating of MoFₓ or MoFₓ and MoOFₓ; and
removing MoFₓ or MoFₓ and MoOFₓ from the member, where x represents a number greater than 0 and less than 6.

2. The method for removing MoFₓ or MoFₓ and MoOFₓ according to claim 1, wherein the halogen-containing gas is a gas of a compound having a bond between a fluorine atom and an atom other than the fluorine atom, and a bond energy between the fluorine atom and the atom other than the fluorine atom is 2.5 eV or less.

3. The method for removing MoFₓ or MoFₓ and MoOFₓ according to claim 2, wherein the bond energy is 1.7 eV or more and 2.5 eV or less.

4. The method for removing MoFₓ or MoFₓ and MoOFₓ according to claim 1, wherein the halogen-containing gas is a fluorine-containing gas.

5. The method for removing MoFₓ or MoFₓ and MoOFₓ according to claim 1, wherein the halogen-containing gas is a fluorine gas.

6. The method for removing MoFₓ or MoFₓ and MoOFₓ according to claim 1, wherein the member with which the halogen-containing gas is brought into contact has a temperature of 0° C. to 400° C.

7. A method for producing a semiconductor device comprising:
(1) circulating a gas containing MoF₆ in a semiconductor processing apparatus including a chamber and a pipe connected to the chamber to bring MoF₆ into contact with a semiconductor substrate; and
(2) bringing a halogen-containing gas into contact with at least one of the chamber and the pipe having a deposit or coating of MoFₓ or MoFₓ and MoOFₓ, where x represents a number greater than 0 and less than 6.

8. The method for producing a semiconductor device according to claim 7, wherein the halogen-containing gas is a gas of a compound having a bond between a fluorine atom and an atom other than the fluorine atom, and a bond energy between the fluorine atom and the atom other than the fluorine atom is 2.5 eV or less.

9. The method for producing a semiconductor device according to claim 8, wherein the bond energy is 1.7 eV or more and 2.5 eV or less.

10. The method for producing a semiconductor device according to claim 7, wherein the halogen-containing gas is a fluorine-containing gas.

11. The method for producing a semiconductor device according to claim 7, wherein the halogen-containing gas is a fluorine gas.

12. The method for producing a semiconductor device according to claim 7, wherein at least one of the chamber or the pipe with which the halogen-containing gas is brought into contact has a temperature of 0° C. to 400° C.
